(19) United States
(12) Patent Application Publication
(10) Pub. No.: US 2018/0139844 A1
(43) Pub. Date: May 17, 2018

(54) ELECTRONIC DEVICE, METHOD FOR FABRICATING AN ELECTRONIC DEVICE, AND SUBSTRATE STRUCTURE

(71) Applicant: Siliconware Precision Industries Co., Ltd., Taichung (TW)

(72) Inventor: Jin-Wei You, Taichung (TW)

(21) Appl. No.: 15/431,834

(22) Filed: Feb. 14, 2017

(30) Foreign Application Priority Data
Nov. 16, 2016 (TW) 105137418

(51) Int. Cl. H05K 1/18; H05K 1/02; H05K 3/10; H05K 3/30; H05K 3/32

(52) U.S. Cl. CPC H05K 1/18; H05K 1/0213; H05K 3/10; H05K 2201/1003; H05K 3/32; H05K 2201/10015; H05K 2201/10022; H05K 3/30

(57) ABSTRACT

An electronic device is provided, including a substrate, a first circuit portion and a second circuit portion formed on the substrate, and an electronic component having a first portion disposed on the first circuit portion and a second portion disposed on the second circuit portion. The first circuit portion differs in circuit specification from the second circuit portion. Therefore, the present disclosure eliminates the need to fabricate all circuit layers under fine trace specification, thereby effectively reducing the cost.

### BACKGROUND

### 1. Technical Field

The disclosure relates to electronic devices and methods for fabricating the same, and, more particularly, to a semiconductor device and a method for fabricating the same.

### 2. Description of Related Art

Along with the rapid development of electronic industries, electronic products are developed toward the trend of multi-function and high performance. Accordingly, there have been developed various types of flip-chip packaging modules such as chip scale packages (CSPs), direct chip attached (DCA) packages and multi-chip modules (MCM), and 3D I C chip stacking technologies.

FIG. 1 is a schematic cross-sectional view of a conventional semiconductor package 1. A silicon interposer 10 is provided between a packaging substrate (not shown) and a semiconductor chip 15. The packaging substrate has a plurality of bonding pads and the semiconductor chip 15 has a plurality of electrode pads 150. The silicon interposer 10 has a plurality of through silicon vias (TSVs) 100 and an RDL (redistribution layer) structure formed on the TSVs 100. The RDL structure has a dielectric layer 11 and a redistribution layer 12 formed on the dielectric layer 11. The electrode pads 150 of the semiconductor chip 15 are electrically connected to the redistribution layer 12 through a plurality of solder bumps 14, and an underfill 13 is formed between the semiconductor chip 15 and the redistribution layer 12 to encapsulate the solder bumps 14. The electrode pads 150 have a small pitch therebetween. Further, the TSVs 100 are electrically connected to the bonding pads of the packaging substrate through a plurality of conductive bumps (not shown). The bonding pads of the packaging substrate have a large pitch therebetween.

Through a semiconductor process, the redistribution layer 12 of the silicon interposer 10 can have a trace width/pitch below 2/2 um. As such, if the semiconductor chip 15 has a high I/O count, the area of the silicon interposer 10 is sufficient for connection with the semiconductor chip 15. Therefore, the semiconductor chip 15 can be electrically connected to the packaging substrate through the silicon interposer 10, thus eliminating the need to increase the area of the packaging substrate.

Further, the fine trace width/pitch of the silicon interposer 10 shortens the electrical transmission path. Therefore, compared with a semiconductor chip directly disposed on the packaging substrate, the semiconductor chip 15 disposed on the silicon interposer 10 achieves a faster electrical transmission speed.

However, the process for forming the fine trace width/pitch requires expensive equipment and is time-consuming. For example, to form the TSVs 100 of the silicon interposer 10, a plurality of through holes need to be formed in a silicon substrate (for example, through a patterning process including such as exposure, development and etching) and filled with metal, which incurs a high fabrication cost. For example, for a 12-inch wafer, the TSV cost accounts for about 40 to 50% of the total cost for fabricating the silicon interposer 10 (not including labor cost). Also, the fabrication process, especially the process of etching the silicon substrate for forming the through holes, consumes a large amount of time. Consequently, it becomes quite difficult to reduce the cost and price of the final product.

Therefore, how to overcome the above-described drawbacks has become critical.

### SUMMARY

In view of the above-described drawbacks, the disclosure provides an electronic device, which comprises: a substrate; a first circuit portion formed on the substrate with a first circuit layer electrically connected to the substrate; a second circuit portion formed on the substrate with a second circuit layer electrically connected to the substrate; and an electronic component disposed on the first circuit portion and the second circuit portion and having a first portion disposed on the first circuit layer and a second portion disposed on the second circuit layer, wherein the first circuit layer differs in circuit specification from the second circuit layer.

The disclosure further provides a method for fabricating an electronic device, which comprises: forming a first circuit portion and a second circuit portion on a substrate, wherein the first circuit portion has a first circuit layer electrically connected to the substrate, the second circuit portion has a second circuit layer electrically connected to the substrate, and the first circuit layer differs in circuit specification from the second circuit layer; and disposing on the first circuit portion and the second circuit portion an electronic component that has a first portion disposed on the first circuit layer and a second portion disposed on the second circuit layer.

The disclosure further provides a substrate structure, which comprises: a substrate; a first circuit portion formed on the substrate with a first circuit layer electrically connected to the substrate; and a second circuit portion formed on the substrate with a second circuit layer electrically connected to the substrate, wherein the first circuit layer differs in circuit specification from the second circuit layer.

In an embodiment, the substrate can comprise a circuit structure. The circuit specification of the circuit structure can be the same as or different from that of the first circuit layer. The substrate can comprise a core layer. Alternatively, the substrate can have a coreless structure.

In an embodiment, an opening can be formed in the first circuit portion so as for the second circuit portion to be formed therein.

In an embodiment, the first circuit portion and the second circuit portion can have equal or unequal heights.

In an embodiment, the second circuit portion can be a circuit board.

In an embodiment, the second circuit layer can be electrically connected to the substrate through a plurality of conductive elements.

In an embodiment, the electronic component can be bonded to the first circuit layer through a plurality of first conductive elements and bonded to the second circuit layer through a plurality of second conductive elements. The first conductive elements and the second conductive elements can have equal or unequal heights.

In an embodiment, another electronic component can further be disposed on the second circuit portion without being disposed on the first circuit portion.

In an embodiment, a bonding material can be formed between the substrate and the electronic component for fixing the electronic component on the first circuit portion and the second circuit portion.

According to the disclosure, the first circuit layer differs in circuit specification from the second circuit layer. Therefore, not all the circuit layers of the electronic device need to be fabricated under fine trace specification. Instead, the circuit layers of the electronic device can be fabricated according to different electrical and performance requirements of the electronic device. Compared with the redistribution layer of the conventional silicon interposer that is fabricated under the fine trace specification, the disclosure reduces the cost.

Further, the second circuit portion can be positioned in the opening of the first circuit portion so as to facilitate transportation and avoid warping in subsequent processes.

### BRIEF DESCRIPTION OF DRAWINGS

FIG. 1 is a schematic cross-sectional view of a conventional semiconductor package;

FIGS. 2A to 2E are schematic cross-sectional views showing a method for fabricating an electronic device according to the disclosure; and

FIGS. 3 to 5 are schematic cross-sectional views showing various embodiments of the electronic device according to the disclosure.

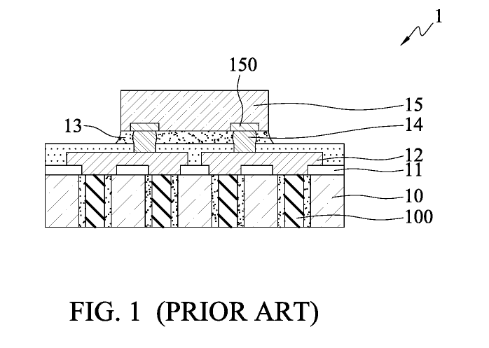

### DETAILED DESCRIPTION OF EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

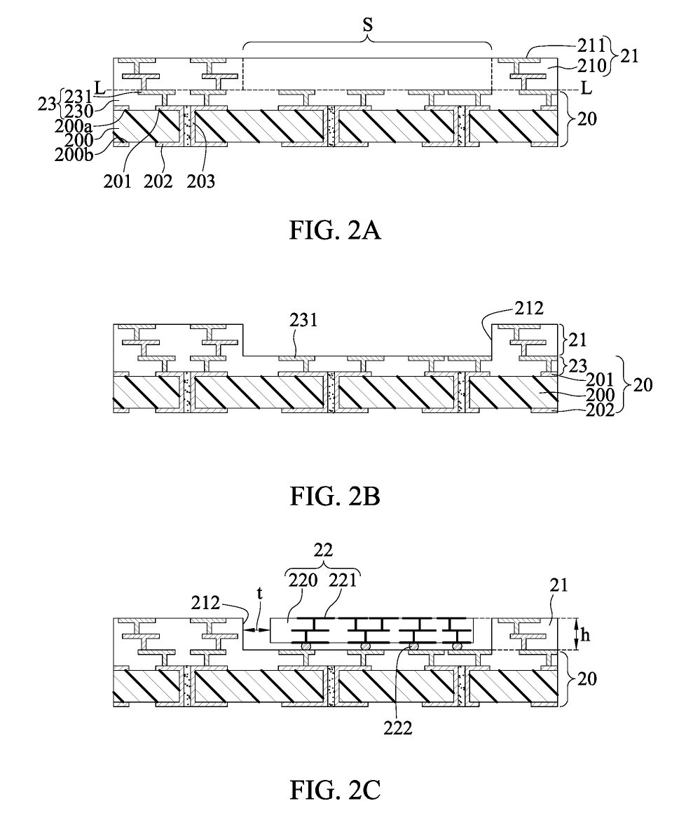

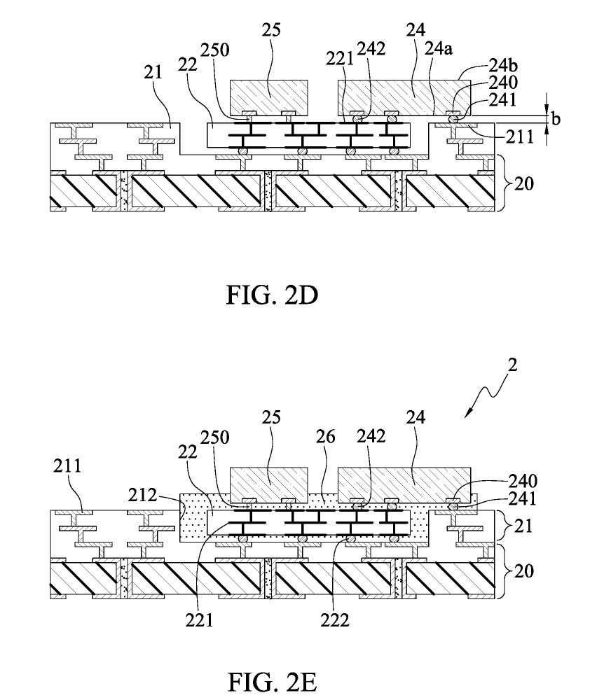

FIGS. 2A to 2E are schematic cross-sectional views showing a method for fabricating an electronic device 2 according to the disclosure.

Referring to FIG. 2A, a substrate 20 having a core layer 200 is provided.

In an embodiment, the core layer 200 has a first surface 200a and a second surface 200b opposite to the first surface 200a. A circuit layer 201 is formed on the first surface 200a of the core layer 200, a circuit layer 202 is formed on the second surface 200b of the core layer 200, and a plurality of conductive through holes 203 are formed in the core layer 200 and electrically connect the circuit layers 201, 202.

Further, a circuit structure 23 is formed on the first surface 200a of the core layer 200 and the circuit layer 201. The circuit structure 23 is, for example, a built-up structure, which has at least one dielectric layer 230 and at least one circuit layer 231 formed on the dielectric layer 230.

Furthermore, a first circuit portion 21 is formed on the circuit structure 23 (on a boundary line L of FIG. 2A). The first circuit portion 21 has at least one dielectric layer 210 and at least one first circuit layer 211 formed on the dielectric layer 210 and electrically connected to the circuit layer 231 of the circuit structure 23.

The circuit structure 23 and the first circuit portion 21 are formed through the same process, for example, a substrate process. The circuit layer 231 of the circuit structure 23 and the first circuit layer 211 of the first circuit portion 21 have the same circuit specification, i.e., trace width/pitch. Both the circuit layer 231 of the circuit structure 23 and the first circuit layer 211 of the first circuit portion 21 have a trace width/pitch above 10/10 um.

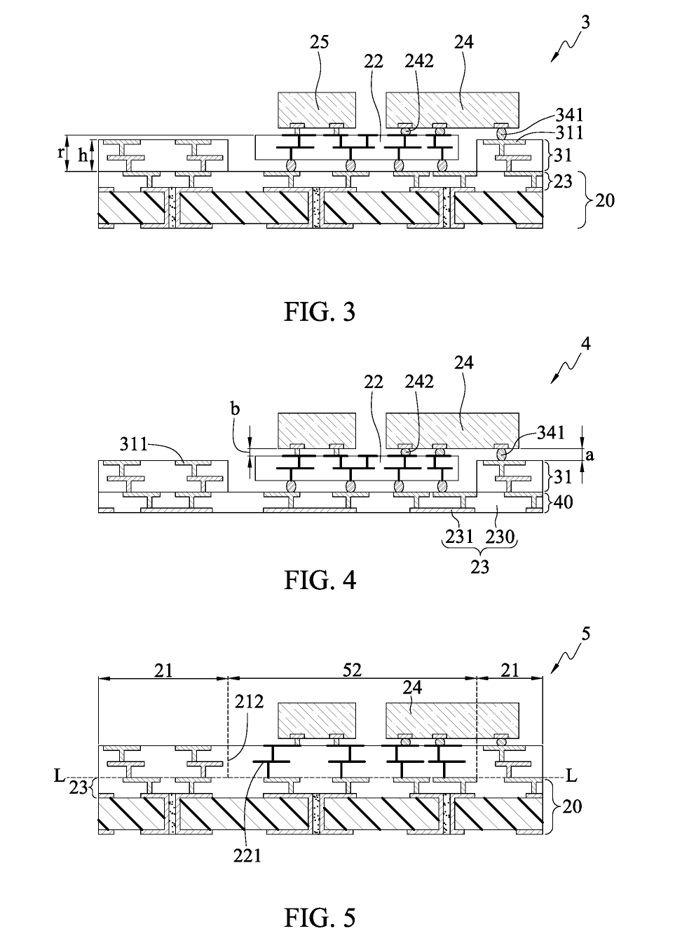

In another embodiment, referring to FIG. 3, the circuit structure 23 and the first circuit portion 31 are formed through different processes. For example, the circuit structure 23 is formed through a substrate process, while the first circuit portion 31 is formed through a semiconductor process. As such, the circuit layer 231 of the circuit structure 23 differs in circuit specification from the first circuit layer 311 of the first circuit portion 31. For example, the first circuit layer 311 formed through the semiconductor process has a trace width/pitch of 2/2 to 10/10 um, and the circuit structure 23 formed through the substrate process has a trace width/pitch above 10/10 um.

Referring to FIG. 2B, a portion of the dielectric layer 210 is removed from the first circuit portion 21 and thus an opening 212 is formed in the first circuit portion 21 to expose a portion of the circuit layer 231 of the circuit structure 23.

In an embodiment, referring to FIG. 2A, an open area S is predefined on the dielectric layer 210 of the first circuit portion 21 so as to prevent formation of the first circuit layer 211 in the open area S. As such, removing the portion of the dielectric layer 210 will not damage the first circuit layer 211.

Referring to FIG. 2C, a pre-fabricated second circuit portion 22 is provided and disposed in the opening 212.

In an embodiment, the second circuit portion 22 is, for example, a circuit board, which has at least one dielectric layer 220 and a second circuit layer 221 formed on the dielectric layer 220. The second circuit layer 221 differs in circuit specification from the first circuit layer 211. For example, the second circuit layer 221 of the second circuit portion 22 is formed through an RDL process and has a trace width/pitch below 2/2 um.

Further, the second circuit portion 22 (such as a circuit board) is disposed on the circuit layer 231 of the circuit structure 23 in the opening 212 through a plurality of conductive elements 222 such as solder bumps or metal posts. As such, the second circuit layer 221 is electrically connected to the substrate 20.

Furthermore, the first circuit portion 21 and the second circuit portion 22 have the same height h relative to the substrate 20. In another embodiment, referring to FIG. 3, the height h of the first circuit portion 21 is not equal to the height r of the second circuit portion 22. For example, r>h.

In an embodiment, the opening 212 is not completely filled by the second circuit portion 22 and a gap t is formed between the second circuit portion 22 and the first circuit portion 21.

Referring to FIG. 2D, an electronic component 24 is disposed on the substrate 20 in a manner that a first portion of the electronic component 24 is disposed on the first circuit layer 211 and a second portion of the electronic component 24 is disposed on the second circuit layer 221. That is, the electronic component 24 is disposed across the first circuit layer 211 and the second circuit layer 221.

In an embodiment, the electronic component 24 is an active component such as a semiconductor chip, a passive component, such as a resistor, a capacitor or an inductor, or a combination thereof. For example, the electronic component 24 has an active surface 24a having a plurality of electrode pads 240 and an inactive surface 24b opposite to the active surface 24a. The electronic component 24 is disposed on the first circuit layer 211 and the second circuit layer 221 in a flip-chip manner.

Further, the electronic component 24 is bonded to the first circuit layer 211 through a plurality of first conductive elements 241, such as solder bumps or metal posts, and bonded to the second circuit layer 221 through a plurality of second conductive elements 242, such as solder bumps or metal posts. In an embodiment, the first conductive elements 241 and the second conductive elements 242 have the same height b relative to the electronic component 24 (the active surface 24a). In another embodiment, referring to FIGS. 3 and 4, the height a of the first conductive elements 341 is not equal to the height b of the second conductive elements 242. For example, a>b.

Furthermore, another electronic component 25 is disposed on the second circuit portion 22 only, and is not disposed on the first circuit portion 21. In an embodiment, the electronic component 25 is electrically connected to the second circuit layer 221 through a plurality of third conductive elements 250, such as solder bumps or metal posts.

Referring to FIG. 2E, a bonding material 26 such as an underfill is formed between the substrate 20 and the electronic components 24, 25 to fix the electronic components 24, 25.

In an embodiment, the bonding material 26 is formed on the first circuit portion 21 and the second circuit portion 22 and in the opening 212 and encapsulates the conductive elements 222, the first conductive elements 241, the second conductive elements 242 and the third conductive elements 250.

In another embodiment, referring to FIG. 4, the substrate 40 is coreless and only has a circuit structure 23.

Referring to FIG. 5, in a further embodiment, continued from the process of FIG. 2B, an RDL process is directly performed in the opening 212 so as to cause the second circuit portion 52 and the first circuit portion 21 to be in close contact with each other without any gap therebetween. Alternatively, the first circuit portion 21 and the second circuit portion 52 of different circuit specifications can be formed on the substrate 20 at the same time. The first circuit layer 211 of the first circuit portion 21 has a trace width/pitch of 2/2 to 10/10 um, and the second circuit layer 221 of the second circuit portion 22 has a trace width/pitch below 2/2 um.

According to the disclosure, some circuits, such as power and ground circuits, do not need to be fine width/pitch. Therefore, the first circuit layer 211, 311 of the first circuit portion 21, 31 can be fabricated to have a larger trace width/pitch (2/2 to 10/10 um) that meets the power/ground circuit specification. As such, a first portion of the electronic component 24 is electrically connected to the first circuit layer 211 through the first conductive elements 241, 341, and a second portion of the electronic component 24 is electrically connected to the second circuit layer 221 (having a trace width/pitch below 2/2 um) through the second conductive elements 242. Compared with the prior art that fabricates all circuit layers (such as the redistribution layer of the silicon interposer) with a trace width/pitch below 2/2 um, the disclosure reduces the cost.

Further, since the second circuit portion 22 can be positioned in the opening 212 of the first circuit portion 21, the disclosure facilitates transportation and avoids warping in subsequent processes.

The disclosure further provides an electronic device 2, 3, 4, 5, which has: a substrate 20, 40 having a circuit structure 23; a first circuit portion 21, 31 formed on the substrate 20, 40 and having a first circuit layer 211, 311 electrically connected to the circuit structure 23; a second circuit portion 22, 52 formed on the substrate 20, 40 and having a second circuit layer 221 electrically connected to the circuit structure 23, wherein the first circuit layer 211, 311 differs in circuit specification from the second circuit layer 221; and an electronic component 24 disposed on the first circuit portion 21, 31 and the second circuit portion 22, 52, wherein a first portion of the electronic component 24 is disposed on the first circuit layer 211, 311 and a second portion of the electronic component 24 is disposed on the second circuit layer 221.

In an embodiment, the substrate 20 has a core layer 200. Alternatively, the substrate 40 has a coreless structure.

In an embodiment, the circuit specification of the circuit structure 23 is the same as or different from that of the first circuit layer 211, 311.

In an embodiment, an opening 212 is formed in the first circuit portion 21, and the second circuit portion 22, 52 is formed in the opening 212.

In an embodiment, the first circuit portion 21 and the second circuit portion 22, 52 have equal or unequal heights.

In an embodiment, the second circuit portion 22 is a circuit board.

In an embodiment, the second circuit layer 221 is electrically connected to the circuit structure 23 through a plurality of conductive elements 222.

In an embodiment, the electronic component 24 is bonded to the first circuit layer 211, 311 through a plurality of first conductive elements 241, 341 and bonded to the second circuit layer 221 through a plurality of second conductive elements 242. For example, the first conductive elements 241, 341 and the second conductive elements 242 have equal or unequal heights.

In an embodiment, the electronic device 2 further has another electronic component 25 disposed on the second circuit portion 22 and not on the first circuit portion 21.

In an embodiment, the electronic device 2 further has a bonding material 26 formed on the substrate 20, 40 for fixing the electronic components 24, 25.

According to the disclosure, the first circuit layer differs in circuit specification from the second circuit layer. Therefore, not all the circuit layers of the electronic device need to be fabricated under fine trace specification. Instead, the circuit layers of the electronic device can be fabricated according to different electrical and performance requirements of the electronic device, thus reducing the cost.

Further, the second circuit portion can be positioned in the opening of the first circuit portion so as to facilitate transportation and avoid warping in subsequent processes.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. A substrate structure, comprising:
a substrate;
a first circuit portion formed on the substrate with a first circuit layer electrically connected to the substrate; and
a second circuit portion formed on the substrate with a second circuit layer electrically connected to the substrate,
wherein the first circuit layer differs in circuit specification from the second circuit layer.

2. The substrate structure of claim 1, wherein the substrate comprises a circuit structure.

3. The substrate structure of claim 2, wherein the circuit structure and the first circuit layer have the same circuit specification.

4. The substrate structure of claim 2, wherein the circuit structure and the first circuit layer have different circuit specification.

5. The substrate structure of claim 1, further comprising an opening formed in the first circuit portion with the second circuit portion formed in the opening.

6. The substrate structure of claim 1, wherein the first circuit portion and the second circuit portion have equal heights.

7. The substrate structure of claim 1, wherein the first circuit portion and the second circuit portion have unequal heights.

8. The substrate structure of claim 1, wherein the second circuit portion is a circuit board.

9. The substrate structure of claim 1, wherein the second circuit layer is electrically connected to the substrate through a plurality of conductive elements.

10. An electronic device, comprising:
the substrate structure according to claim 1; and
an electronic component disposed on the first circuit portion and the second circuit portion, and having a first portion disposed on the first circuit layer and a second portion disposed on the second circuit layer.

11. The electronic device of claim 10, wherein the substrate comprises a core layer.

12. The electronic device of claim 10, wherein the substrate has a coreless structure.

13. The electronic device of claim 10, wherein the electronic component is bonded to the first circuit layer through a plurality of first conductive elements and bonded to the second circuit layer through a plurality of second conductive elements.

14. The electronic device of claim 13, wherein the first conductive elements and the second conductive elements have equal heights.

15. The electronic device of claim 13, wherein the first conductive elements and the second conductive elements have unequal heights.

16. The electronic device of claim 10, further comprising another electronic component disposed on the second circuit portion and free from being disposed on the first circuit portion.

17. The electronic device of claim 10, further comprising a bonding material formed on the substrate for fixing the electronic component.

18. A method for fabricating an electronic device, comprising:
forming a first circuit portion and a second circuit portion on a substrate, wherein the first circuit portion has a first circuit layer electrically connected to the substrate, the second circuit portion has a second circuit layer electrically connected to the substrate, and the first circuit layer differs in circuit specification from the second circuit layer; and
disposing on the first circuit portion and the second circuit portion an electronic component having a first portion disposed on the first circuit layer and a second portion disposed on the second circuit layer.

19. The method of claim 18, wherein the substrate comprises a circuit structure.

20. The method of claim 19, wherein the substrate comprises a core layer.

21. The method of claim 19, wherein the substrate has a coreless structure.

22. The method of claim 19, wherein the circuit structure and the first circuit layer have the same circuit specification.

23. The method of claim 19, wherein the circuit structure and the first circuit layer have different circuit specification.

24. The method of claim 18, wherein the first circuit portion has an opening with the second circuit portion formed in the opening.

25. The method of claim 18, wherein the first circuit portion and the second circuit portion have equal heights.

26. The method of claim 18, wherein the first circuit portion and the second circuit portion have unequal heights.

27. The method of claim 18, wherein the second circuit portion is a circuit board.

28. The method of claim 18, wherein the second circuit layer is electrically connected to the substrate through a plurality of conductive elements.

29. The method of claim 18, wherein the electronic component is bonded to the first circuit layer through a plurality of first conductive elements and bonded to the second circuit layer through a plurality of second conductive elements.

30. The method of claim 29, wherein the first conductive elements and the second conductive elements have equal heights.

31. The method of claim 29, wherein the first conductive elements and the second conductive elements have unequal heights.

32. The method of claim 18, further comprising disposing another electronic component on the second circuit portion with the another electronic component free from being disposed on the first circuit portion.

33. The method of claim 18, further comprising forming a bonding material between the substrate and the electronic component for fixing the electronic component on the first circuit portion and the second circuit portion.
